(19) United States
(12) Patent Application Publication
(10) Pub. No.: US 2022/0013655 A1
(43) Pub. Date: Jan. 13, 2022

(54) SEMICONDUCTOR DEVICE AND METHOD FOR PREPARING SAME

(71) Applicant: CHANGXIN MEMORY TECHNOLOGIES, INC., Hefei City (CN)

(72) Inventors: Gongyi WU, Hefei (CN); Yafei HUANG, Hefei (CN); Yong LU, Hefei (CN)

(21) Appl. No.: 17/392,439

(22) Filed: Aug. 3, 2021

Related U.S. Application Data
(63) Continuation of application No. PCT/CN2021/095550, filed on May 24, 2021.

(30) Foreign Application Priority Data
Jul. 10, 2020 (CN) 202010662901.2

(51) Int. Cl. H01L 29/66; H01L 21/8234; H01L 21/768; H01L 29/78

(52) U.S. Cl. CPC H01L 29/66689; H01L 21/823437; H01L 29/7816; H01L 21/76841; H01L 21/823468; H01L 21/823462

(57) ABSTRACT

A method for preparing a semiconductor device includes the following operations. A semiconductor substrate is provided, and a gate dielectric layer, a first conductive layer, and a support layer with a through hole are sequentially formed on the semiconductor substrate. A barrier layer and a second conductive layer are formed in the through hole. The support layer and a part of the first conductive layer located below the support layer are removed to form a primary gate pattern and expose the gate dielectric layer. A gate sidewall protective layer is formed on a sidewall of the primary gate pattern. An insulating layer is formed on a top of the primary gate pattern, a surface of the gate sidewall protective layer and a surface of the exposed part of the gate dielectric layer. A part of the insulating layer and a part of the gate dielectric layer are removed.

### CROSS-REFERENCE TO RELATED APPLICATION

This application is a U.S. continuation application of International Application No. PCT/CN2021/095550, filed on May 24, 2021, which claims priority to Chinese Patent Application No. 202010662901.2, filed on Jul. 10, 2020. International Application No. PCT/CN2021/095550 and Chinese Patent Application No. 202010662901.2 are incorporated herein by reference in their entireties.

### TECHNICAL FIELD

This disclosure relates to the technical field of semiconductors, and in particular to a semiconductor device and a method for preparing the same.

### BACKGROUND

In the related art, as the size of the gate becomes smaller and smaller, the distance between the source region and the drain region of the Metal-Oxide-Semiconductor Field Effect Transistor (MOSFET) becomes shorter and shorter. Thereby, the device is prone to produce a short channel effect and a hot carrier effect, causing components to fail to operate. In order to improve the above problems, the Lightly Doped Drain (LDD) structure is designed in the source/drain of the existing MOSFET devices with micron-level and the following manufacturing process. That is, a low-doped region with a shallow depth and the same doping state as the source/drain region is formed in the part adjacent to the source/drain region below the gate structure, so as to reduce the electric field in the channel region, thereby avoiding the occurrence of the short channel effect and the hot carrier effect. In the existing mainstream technologies, Atomic Layer Deposition (ALD) is used to form an insulating layer on the surface of metal/polysilicon gate before forming the LDD structure. Atomic layer deposition is a thin film deposition process based on ordered and surface self-saturation reaction. The self-limiting growth of the thin film is realized by alternating saturated surface reactions, and the substance is plated on the substrate surface layer by layer in the form of a single atomic film. Compared with Physical Vapor Deposition (PVD) and Chemical Vapor Deposition (CVD), ALD deposition has a slower reaction rate, better film uniformity, and film coverage, and is more suitable for the formation of a pattern that requires particularly high film uniformity. Although the uniformity of the thin film formed by ALD will be better, there is still a big gap with the ideal requirements, especially the difference in the growth rate on the surface of different substrate materials, which has always been the “bottleneck” restricting the development of ALD technology. During the atomic layer deposition of the gate insulating layer, since the difference in the growth rate on the surfaces of the conductive layer and the passivation layer of the gate structure causes the uneven thickness of the insulating layer, resulting in abnormalities in sidewall profile of the gate structure. The thickness of the top of the gate structure is greater than the thickness of the bottom thereof, and thus a “T”-shaped structure is formed. In the subsequent processes of forming the LDD structure, since the thickness of the top of the “T”-shaped structure is too big to block the ion implantation, the LDD structure at the bottom is abnormal. In addition, with the continuous improvement in the integration level of the semiconductor device, the thickness of the gate insulating layer is continuously reduced, so that the gate is prone to take place metal migration and device displacement, thereby causing yield loss of the semiconductor device. How to solve this problem in the process has also become a big challenge.

### SUMMARY

The objective of this disclosure is to provide a method for preparing a semiconductor device.

A method for preparing a semiconductor device according to embodiments of this disclosure includes the following operations. A semiconductor substrate is provided, and a gate dielectric layer, a first conductive layer, and a support layer with a through hole are sequentially formed on the semiconductor substrate. A barrier layer and a second conductive layer are formed in the through hole of the support layer, and the barrier layer is formed between the support layer and the second conductive layer and covers an inner wall face of the through hole. The support layer and a part of the first conductive layer located below the support layer are removed to form a primary gate pattern and expose the gate dielectric layer. A gate sidewall protective layer is formed on a sidewall of the primary gate pattern. An insulating layer is formed on a top of the primary gate pattern, a surface of the gate sidewall protective layer and a surface of the exposed part of the gate dielectric layer. A part of the insulating layer and a part of the gate dielectric layer are removed to retain the insulating layer formed on the top of the primary gate pattern and the surface of the gate sidewall protective layer, and to retain the gate dielectric layer covered by the primary gate pattern, the gate sidewall protective layer, and the insulating layer on the surface of the gate sidewall protective layer.

This disclosure further proposes a semiconductor device.

The semiconductor device according to embodiments of this disclosure includes: a semiconductor substrate, on which a gate dielectric layer is formed; and a gate structure, formed on the gate dielectric layer, and comprising a first conductive layer, a barrier layer, a gate sidewall protective layer, a second conductive layer, and an insulating layer arranged in sequence. The barrier layer wraps a bottom face and a side face of the second conductive layer, and the insulating layer is formed on a surface of the gate sidewall protection layer and tops of the second conductive layer and the barrier layer.

### BRIEF DESCRIPTION OF THE DRAWINGS

FIG. 1 schematically illustrates a flowchart of a method for preparing a semiconductor device according to embodiments of this disclosure.

FIG. 2 to FIG. 14 illustrate flowcharts of operations of a method for preparing a semiconductor structure according to embodiments of this disclosure respectively.

### REFERENCE SIGNS IN THE DRAWINGS

1000: semiconductor device;
100: a semiconductor substrate;
200: gate dielectric layer;
300: first conductive layer;
400: support layer; 401: mask layer; 402: photoresist layer; 403: through hole;
500: barrier layer;
600: second conductive layer;
700: insulating layer;
900: gate sidewall protective layer; 901: second protective layer. 902: first protective layer

### DETAILED DESCRIPTION

A semiconductor device and a method for preparing the same proposed in this disclosure will be further described below in detail with reference to the accompanying drawings and specific examples. Through the disclosure, migration in materials of the gate metal can be avoided, and good uniformity of the gate insulating layer can be ensured, thereby improving the product yield rate.

A method for preparing a semiconductor device 1000 according to an example of this disclosure will be described below with reference to the accompanying drawings.

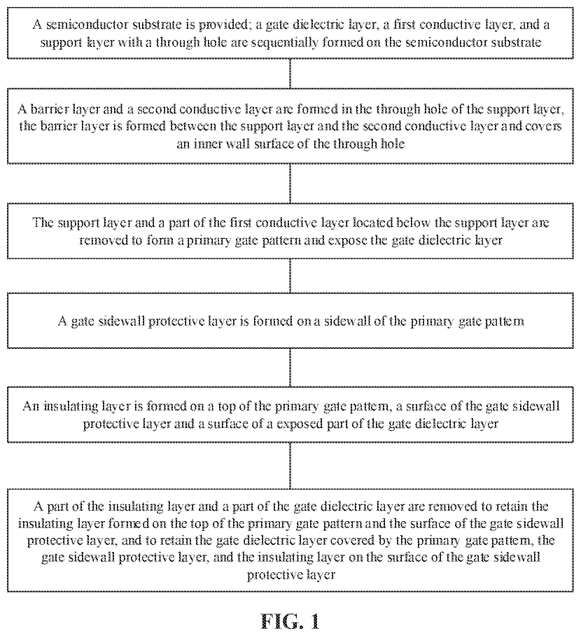

As shown in FIG. 1, the method for preparing the semiconductor device 1000 according to an example of this disclosure may include the following operations. A semiconductor substrate 100 is provided. A gate dielectric layer 200, a first conductive layer 300, and a support layer 400 with a through hole 403 are sequentially formed on the semiconductor substrate 100. A barrier layer 500 and a second conductive layer 600 are formed in the through hole 403 of the support layer 400. The barrier layer 500 is formed between the support layer 400 and the second conductive layer 600 and covers an inner wall face of the through hole 403. The support layer 400 and a part of the first conductive layer 300 located below the support layer 400 are removed to form a primary gate pattern and expose the gate dielectric layer 200. A gate sidewall protective layer is formed on a sidewall of the primary gate pattern. An insulating layer 700 is formed on a top of the primary gate pattern, a surface of the gate sidewall protective layer 900 and a surface of the exposed part of the gate dielectric layer 200. A part of the insulating layer 700 and a part of the gate dielectric layer 200 are removed to retain the insulating layer 700 formed on the top of the primary gate pattern and the surface of the gate sidewall protective layer 900, and to retain the gate dielectric layer 200 covered by the primary gate pattern, the gate sidewall protective layer 900, and the insulating layer 700 on the surface of the gate sidewall protective layer 900.

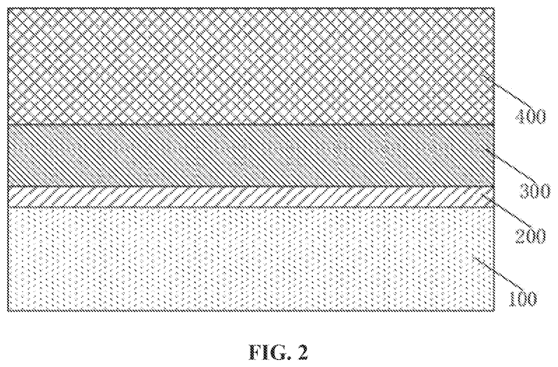

FIG. 2 to FIG. 14 illustrate flowcharts of operations of a method for preparing a semiconductor device 1000 according to embodiments of this disclosure. The method for preparing the semiconductor device 1000 according to an example of this disclosure will be described below with reference to FIG. 2 to FIG. 14.

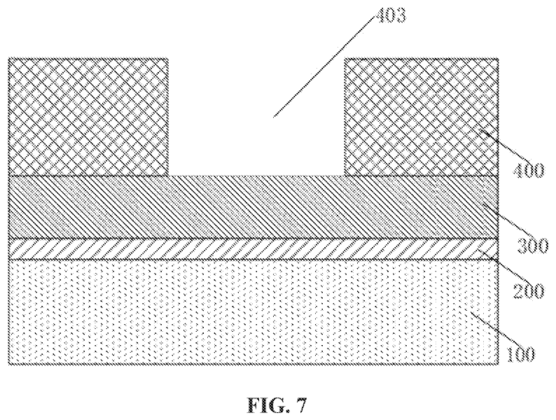

As shown in FIG. 7, a gate dielectric layer 200, a first conductive layer 300, and a support layer 400 with a through hole are sequentially formed on the semiconductor substrate 100 in a direction from bottom to top. The material of the semiconductor substrate 100 may be silicon (Si), germanium (Ge), silicon germanium (GeSi) or silicon carbide (SiC), and may also be silicon on insulator (SOD, germanium on insulator (GOI), or may be other materials, such as III-V compounds, e.g., gallium arsenide and. Devices may further be arranged on the semiconductor substrate 100.

The material of the gate dielectric layer 200 may be silicon oxide, germanium oxide, or a high dielectric constant material, etc. The gate dielectric layer 200 may be formed on the semiconductor substrate 100 by thermal oxidation or chemical vapor deposition, and other processes. The first conductive layer 300 is formed on an upper surface of the gate dielectric layer 200. For the first conductive layer 300, it may be formed on the gate dielectric layer 200 through chemical vapor deposition (CVD) and other processes, and its material may be a conductive material containing silicon element.

For the process for the formation of the through hole 403, as shown in FIG. 2 to FIG. 7, the formation of the support layer 400 with the through hole 403 may include the following operations. The support layer 400, a mask layer 401 and a photoresist layer 402 are formed on the first conductive layer 300. The photoresist layer 402 is patterned, and the photoresist layer 402 in a region where the primary gate pattern needs to be formed is removed. The pattern of the photoresist layer 402 is transferred to the mask layer 401 to form a patterned mask layer 401. A part of the support layer 400 is removed with taking the mask layer 401 as a mask. The mask layer 401 and the photoresist layer 402 are removed to form the support layer 400 with the through hole 403.

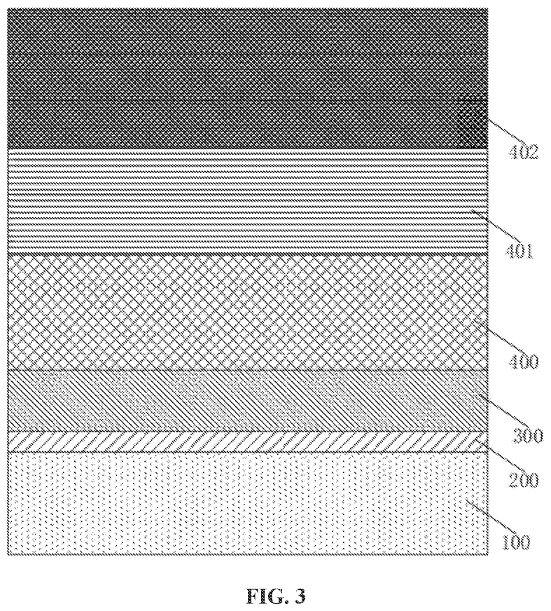

Specifically, as shown in FIG. 2 to FIG. 3, the support layer 400 covering an upper surface of the first conductive layer 300 is formed on the first conductive layer 300, and the mask layer 401 and the photoresist layer 402 may be formed on the support layer 400. The mask layer 401 may include silicon oxynitride as a Dielectric Anti-Reflection Coating (DARC), and an amorphous carbon (a-C) layer as a pattern layer. In some specific examples, a layer of Bottom Anti-Reflection Coating (BARC) and a Photo Resist (PR) layer may further be deposited on the mask layer 401. The photoresist layer 402 is formed on the bottom anti-reflection coating.

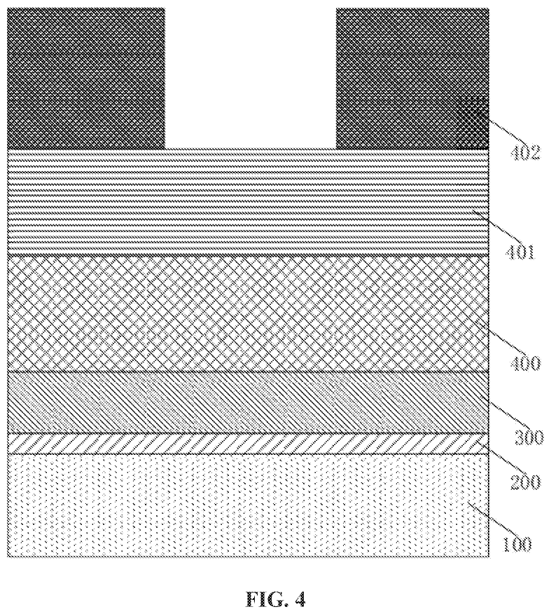

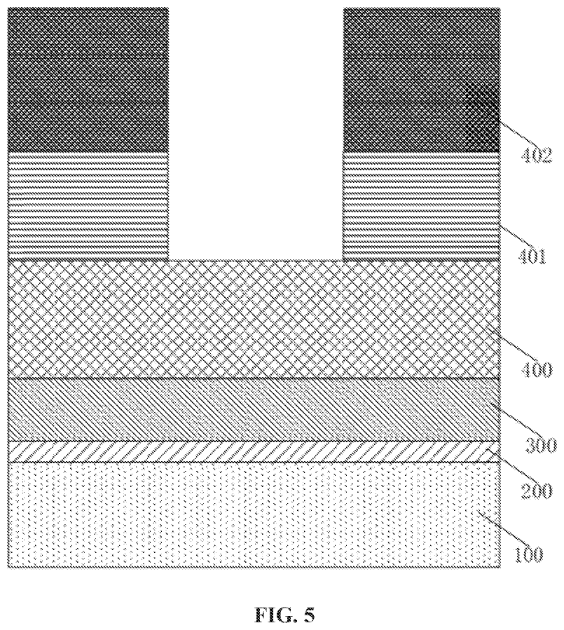

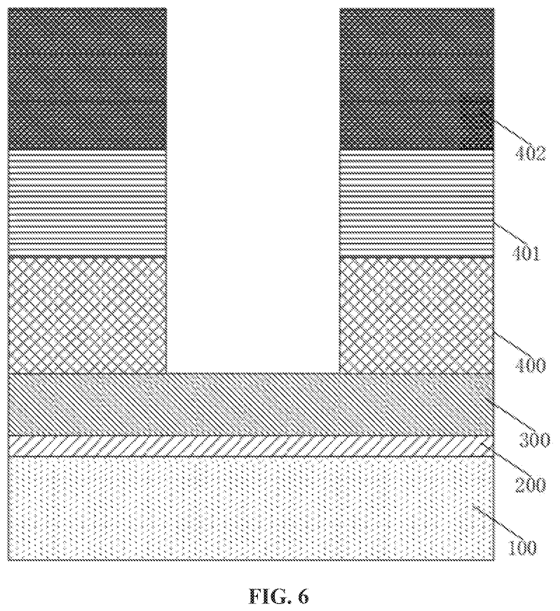

As shown in FIG. 4, the photoresist layer 402 is patterned, and the region where the primary gate pattern needs to be formed is removed. That is, a region where the through hole 403 needs to be formed is removed. As shown in FIG. 5, the pattern of the photoresist layer 402 is transferred to the mask layer 401 to form the patterned mask layer 401. As shown in FIG. 6, taking the mask layer 401 as a mask, a part of the support layer 400 that is not covered by the mask layer 401 is removed, while the support layer 400 covered by the mask layer 401 is retained. As shown in FIG. 7, remaining part of the mask layer 401 and remaining part of the photoresist layer 402 are removed to form a through hole 403 in the support layer 400 that exposes the first conductive layer 300.

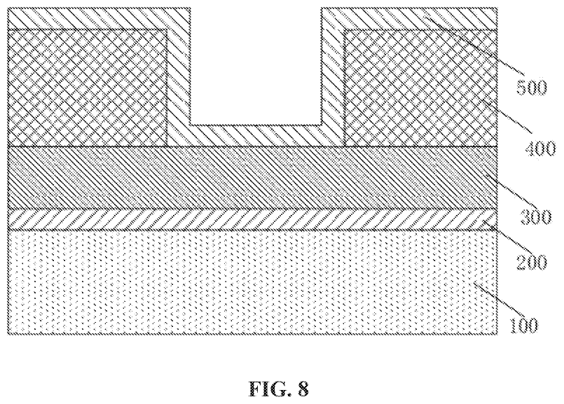

As shown in FIG. 8 to FIG. 10, a barrier layer 500 and a second conductive layer 600 are formed in the through hole 403 of the support layer 400. The barrier layer 500 is formed between the support layer 400 and the second conductive layer 600 and covers an inner wall face of the through hole 403. In this way, the second conductive layer 600 is partially wrapped by the barrier layer 500, which can not only prevent the migration of metal materials in the second conductive layer 600, but also facilitate to protect the gate and avoid the deformation of the gate structure caused by high temperature, oxidation and aging.

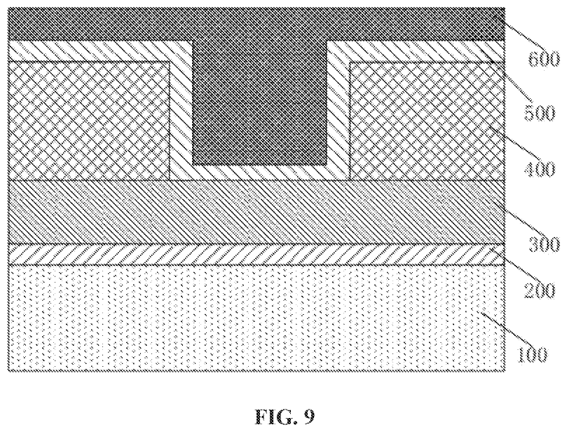

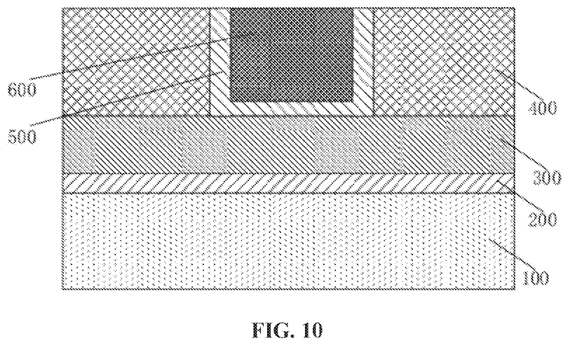

Specifically, as shown in FIG. 8, the barrier layer 500 is formed on a surface of the support layer 400 and in the through hole 403 by deposition. Optionally, the barrier layer 500 may be a titanium-containing material layer, such as a titanium nitride layer, etc. The deposition process may be a process, such as chemical vapor deposition, etc. As shown in FIG. 9, the second conductive layer 600 is formed on a surface of the barrier layer 500 by deposition. In this operation, the second conductive layer 600 may be deposited on the surface of the barrier layer 500 by using a process such as chemical vapor deposition or physical vapor deposition. The second conductive layer 600 may be a tungsten-containing material layer, such as a metal tungsten layer. As shown in FIG. 10, a part of the second conductive layer 600 and a part of the barrier layer 500 are removed to retain the second conductive layer 600 and barrier layer 500 located in the through hole 403. Specifically, in this operation, the second conductive layer 600 and the barrier layer 500 beyond the upper surface of the support layer 400 are removed to retain the second conductive layer 600 and the barrier layer 500 located in the through hole 403. The barrier layer 500 covers the inner wall face of the through hole 403 and wraps the side face and the bottom face of the second conductive layer 600.

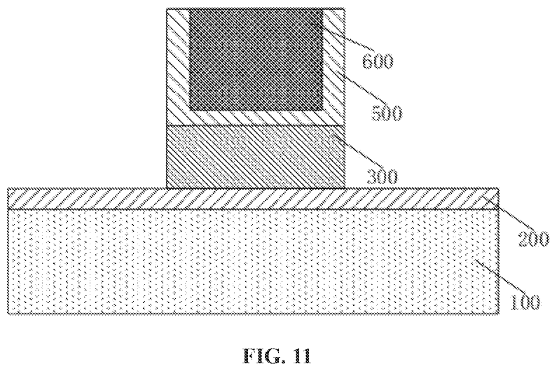

As shown in FIG. 11, the support layer 400 and a part of the first conductive layer 300 located below the support layer 400 are removed to form a primary gate pattern and expose the gate dielectric layer 200. Optionally, in this operation, an anisotropic etching process may be used to remove the support layer 400 and the part of the first conductive layer 300, so that the etching direction can be controlled by using the anisotropic etching process. Therefore, the support layer 400 and the part of the first conductive layer 300 covered by the support layer 400 can be removed in the up and down direction.

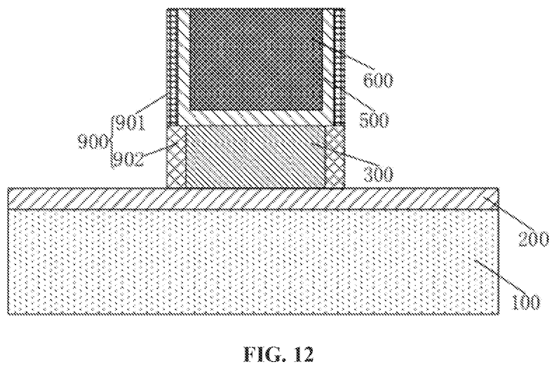

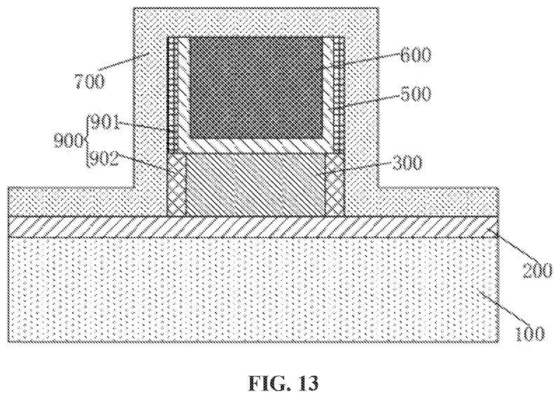

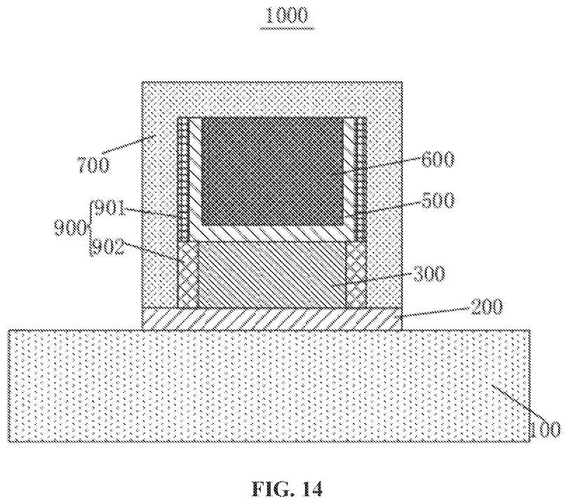

As shown in FIG. 12, a gate sidewall protective layer 900 is formed on a sidewall of the primary gate pattern. As shown in FIG. 13, an insulating layer 700 is formed on a top of the primary gate pattern, a surface of the gate sidewall protective layer 900, and a surface of the exposed part of the gate dielectric layer 200. As shown in FIG. 14, a part of the insulating layer 700 and a part of the gate dielectric layer 200 are removed to retain the insulating layer 700 formed on the top of the primary gate pattern and the surface of the gate sidewall protective layer 900, and to retain the gate dielectric layer 200 covered by the primary gate pattern, the gate sidewall protective layer 900, and the insulating layer 700 on the surface of the gate sidewall protective layer 900.

In some examples of this disclosure, as shown in FIG. 12, the formation of the gate sidewall protective layer 900 may include the following operations. The primary gate pattern is subjected with plasma treatment to form a first protective layer 902 on a sidewall of the first conductive layer 300, and form a second protective layer 901 on a sidewall of the barrier layer 500. The first protective layer 902 and the second protective layer 901 constitute the gate sidewall protective layer 900. The gate sidewall protective layer 900 is formed on the side face of the primary gate structure by plasma treatment, which is not only beneficial to the protection of the sidewall, but also can further improve the problem of uniformity of the gate sidewall insulation layer during the subsequent deposition of the insulating layer 700. Therefore, it is can ensure that the insulating layer on the surface of the first protective layer 902 is flush with the insulating layer on the surface of the second protective layer 901, avoiding forming a “T”-shaped structure and ensuring the normal structure of the device. Further, the sidewall of the primary gate pattern is subjected with plasma treatment by performing in-situ plasma treatment. That is, plasma treatment is directly carried out in the process chamber where the primary gate pattern is formed, which can avoid the long-term exposure of the subsequently formed primary gate pattern and prevent the sidewall of the primary gate pattern from being oxidized to cause the deformation of the gate structure.

Optionally, the sidewall of the primary gate pattern is subjected with plasma treatment by performing a nitrogen and oxygen mixed plasma treatment on the sidewall of the primary gate pattern. The proportion of nitrogen is greater than that of oxygen. That is, in a volume of mixed gas, the content of nitrogen is greater than that of oxygen. For example, the barrier layer 500 may be made of a material containing titanium element, the first conductive layer 300 may be a conductive layer containing silicon element, and the plasma may be a mixture of nitrogen and oxygen. Therefore, through a plasma reaction, the second protective layer 901 containing nitrogen, oxygen and titanium element may be formed on the sidewall of the barrier layer 500, and the first protective layer 902 containing nitrogen, oxygen and silicon element may be formed on the sidewall of the first conductive layer 300. Both the first protective layer 902 and the second protective layer 901 contain a large amount of nitrogen and oxygen. When subsequently depositing the insulating layer 700, it can be ensured that the insulating layer 700 deposited on the surfaces of the first protective layer 902 and the second protective layer 901 has good uniformity, as the elements in material of the first protective layer 902 and the second protective layer 901 are similar.

Further, in the operation of plasma treatment, plasma treatment is performed for a time of 20 s to 60 s. The flow rate of nitrogen is 200 sccm to 800 sccm, and the flow rate of oxygen is 50 sccm to 400 sccm. In the operation of plasma treatment, plasma treatment is performed under a temperature of 20° C. to 80° C.

A semiconductor device 1000 according to embodiments this disclosure will be described below with reference to the accompanying drawings. The semiconductor device 1000 can be prepared by using the method for preparing the semiconductor device mentioned by the above examples.

As shown in FIG. 14, the semiconductor device 1000 according to an example of this disclosure may include a semiconductor substrate 100 and a gate structure.

Specifically, a gate dielectric layer 200 covers a part of an upper surface of the semiconductor substrate 100. The material of the semiconductor substrate 100 may be silicon (Si), germanium (Ge), silicon germanium (GeSi) or silicon carbide (SiC), and may also be silicon on insulator (SOI), germanium on insulator (GOI), or may be other materials, such as other III-V compounds, e.g., gallium arsenide. The semiconductor substrate 100 may further be arranged with devices. The material of the gate dielectric layer 200 may be silicon oxide, germanium oxide, or a high dielectric constant material, etc. The gate dielectric layer 200 may be formed on the semiconductor substrate 100 by thermal oxidation or chemical vapor deposition, and other processes.

The gate structure is formed on the gate dielectric layer 200, and comprises a first conductive layer 300, a barrier layer 500, a gate sidewall protective layer 900, a second conductive layer 600, and an insulating layer 700 arranged in sequence. The barrier layer 500 wraps a bottom face and a side face of the second conductive layer 600. For example, as shown in FIG. 14, on the cross section of the semiconductor device 1000, the barrier layer 500 may form as a U-shaped structure, and the second conductive layer 600 is filled and formed in the barrier layer 500. Therefore, the barrier layer 500 wraps the second conductive layer 600, which can avoid migration in material of the second conductive layer 600, and can also avoid oxidation of the side face of the second conductive layer 600 to cause abnormalities in the gate structure.

For the material of the barrier layer 500, the barrier layer 500 may be formed of a titanium-containing material such as titanium nitride, and the second conductive layer 600 may be a tungsten-containing material layer such as a metal tungsten layer. The barrier layer 500 may prevent the migration of tungsten, ensure the normality of the gate structure, and further avoid the displacement of the device, thereby ensuring the reliability of the device.

The insulating layer 700 is formed on the surface of the gate sidewall protective layer 900 and the topes of the second conductive layer 600 and the barrier layer 500. Specifically, the gate sidewall protective layer 900 includes the second protective layer 901 formed on the sidewall of the barrier layer 500 and the first protective layer 902 formed on the sidewall of the first conductive layer 300 after plasma treatment. The first protective layer 902 covers the side face of the first conductive layer 300 and the second protective layer 901 covers the side face of the barrier layer 500. The mixture of nitrogen and oxygen may be used in plasma treatment of the barrier layer 500 and the first conductive layer 300. The first conductive layer 300 may be made of a conductive material containing silicon, so that the plasma reaction may be carried out on the sidewall of the first conductive layer 300 to form the first protective layer 902 containing nitrogen, oxygen, and silicon elements. The barrier layer 500 may be formed of a titanium-containing material, i.e., titanium nitride. The plasma reaction may be carried out on the sidewall of the barrier layer 500 to form the second protective layer 901 containing nitrogen, oxygen, and titanium elements.

Further, the side face of the first protective layer 902 may be flush with the side face of the second protective layer 901, and the side face of the gate dielectric layer 200 may be flush with the side face of the insulating layer 700 on the sidewall of the first protective layer 902 and the side face of the insulating layer 700 on the sidewall of the second protective layer 901. Therefore, the gate structure is formed with the side face in a flat structure rather than an uneven structure, which can greatly improve the reliability of the semiconductor device.

Further, a thickness of the first protective layer 902 is 5 to 20 angstroms, and a thickness of the second protective layer 901 is 3 to 10 angstroms. If the total thickness of the first protective layer 902 and the second protective layer 901 is too thin, the purpose of preventing oxidation of the sidewall of the device cannot be achieved, and the uniformity of the insulating layer subsequently deposited on the sidewall protective layer cannot be guaranteed. If the total thickness of the first protective layer 902 and the second protective layer 901 is too thick, a total thickness of the first conductive layer 300 and the barrier layer 500 will be too small, which affects the resistance of the gate, and further affects the performance of the device.

The above are only optional embodiments of this disclosure. It should be pointed out that for those of ordinary skill in the art, without departing from the principles of this disclosure, several improvements and modifications can be made, and these improvements and modifications should also be treated as the protection scope of this application.

1. A method for preparing a semiconductor device, comprising:
providing a semiconductor substrate, and sequentially forming a gate dielectric layer, a first conductive layer, and a support layer with a through hole on the semiconductor substrate;
forming a barrier layer and a second conductive layer in the through hole of the support layer, the barrier layer being formed between the support layer and the second conductive layer and covering an inner wall face of the through hole;
removing the support layer and a part of the first conductive layer located below the support layer to form a primary gate pattern and expose the gate dielectric layer;
forming a gate sidewall protective layer on a sidewall of the primary gate pattern;
forming an insulating layer on a top of the primary gate pattern, a surface of the gate sidewall protective layer and a surface of the exposed part of the gate dielectric layer; and
removing a part of the insulating layer and a part of the gate dielectric layer to retain the insulating layer formed on the top of the primary gate pattern and the surface of the gate sidewall protective layer, and to retain the gate dielectric layer covered by the primary gate pattern, the gate sidewall protective layer, and the insulating layer on the surface of the gate sidewall protective layer.

2. The method for preparing the semiconductor device of claim 1, wherein said forming the barrier layer and the second conductive layer in the through hole of the support layer, the barrier layer being formed between the support layer and the second conductive layer and covering an inner wall surface of the through hole comprises:
depositing and forming the barrier layer on a surface of the support layer and in the through hole;
depositing and forming the second conductive layer on a surface of the barrier layer; and
removing a part of the second conductive layer and a part of the barrier layer to retain the second conductive layer and the barrier layer located in the through hole.

3. The method for preparing the semiconductor device of claim 1, wherein the formation of the gate sidewall protective layer comprises:
subjecting the primary gate pattern with plasma treatment to form a first protective layer on a sidewall of the first conductive layer, and form a second protective layer on a sidewall of the barrier layer.

4. The method for preparing the semiconductor device of claim 3, wherein the sidewall of the primary gate pattern is subjected with plasma treatment by performing a nitrogen and oxygen mixed plasma treatment on the sidewall of the primary gate pattern.

5. The method for preparing the semiconductor device of claim 4, wherein the sidewall of the primary gate pattern is subjected with plasma treatment by performing in-situ plasma treatment.

6. A semiconductor device, comprising:
a semiconductor substrate, wherein a gate dielectric layer is formed on the semiconductor substrate; and
a gate structure, formed on the gate dielectric layer, and comprising a first conductive layer, a barrier layer, a gate sidewall protective layer, a second conductive layer, and an insulating layer arranged in sequence, wherein the barrier layer wraps a bottom face and a side face of the second conductive layer, and the insulating layer is formed on a surface of the gate sidewall protection layer and tops of the second conductive layer and the barrier layer.

7. The semiconductor device of claim 6, wherein the gate sidewall protective layer comprises a first protective layer on a sidewall of the first conductive layer and a second protective layer on a sidewall of the barrier layer.

8. The semiconductor device of claim 7, wherein a thickness of the first protective layer is 5 to 20 angstroms, and a thickness of the second protective layer is 3 to 10 angstroms.

9. The semiconductor device of claim 7, wherein a side face of the first protective layer is flush with a side face of the second protective layer.

10. The semiconductor device of claim 7, wherein a side face of the gate dielectric layer is flush with a side face of the insulating layer on a sidewall of the first protective layer and a side face of the insulating layer on a sidewall of the second protective layer.
